(19) United States
(12) Patent Application Publication
(10) Pub. No.: US 2019/0019905 A1
(43) Pub. Date: Jan. 17, 2019

(54) SEMICONDUCTOR RADIATION DETECTOR BASED ON BI-BASED QUATERNARY HALIDE SINGLE CRYSTAL AND MANUFACTURING METHOD THEREOF

(71) Applicant: Huazhong University of Science and Technology, Wuhan, Hubei (CN)

(72) Inventors: Jiang TANG, Wuhan, Hubei (CN); Weicheng PAN, Wuhan, Hubei (CN); Haodi WU, Wuhan, Hubei (CN); Jiajun LUO, Wuhan, Hubei (CN); Guangda NIU, Wuhan, Hubei (CN); Ying ZHOU, Wuhan, Hubei (CN)

(21) Appl. No.: 16/069,019

(22) PCT Filed: Nov. 24, 2017
(86) PCT No.: PCT/CN2017/112762

§ 371 Date: Jul. 10, 2018

(30) Foreign Application Priority Data
Nov. 29, 2016 (CN) 201611071705.8

(51) Int. Cl. H01L 31/032; H01L 31/115; H01L 31/18; H01L 31/0224

(52) U.S. Cl. CPC H01L 31/032; H01L 31/022408; H01L 31/18; H01L 31/115

(57) ABSTRACT

The present invention discloses a semiconductor radiation detector based on Bi-based quaternary halide single crystal and a manufacturing method, and relates to the technical field of ray imaging detector manufactured by a semiconductor material. The semiconductor radiation detector in this example includes: a light absorption layer made of Bi-based quaternary halide single crystal; an electron selective contact layer and a hole selective contact layer respectively provided on upper and lower sides of the light absorption layer; and two electrodes which are respectively in contact with the two charge selective contact layers and used as positive and negative electrodes of the device. The semiconductor radiation detector in the present invention has advantages such as high sensitivity, good stability and environmental friendliness.

### BACKGROUND OF THE PRESENT INVENTION

### Field of the Present Invention

The present invention belongs to the technical field of ray imaging detector manufactured by a semiconductor material, and more particularly, relates to a X-ray and gamma-ray imaging detector manufactured by Bi-based quaternary halide single crystal and a manufacturing method thereof.

### Description of the Related Art

Ray imaging technology uses radioactive rays (such as X-ray and gamma ray) as a medium to obtain information on the structure or function of the detected object to be displayed in the form of an image, provides various industries with technical means for diagnosis, detection and monitoring of the observed objects, and is widely used in medical and health, public safety and high-end manufacturing and other industries. The detector is an important part of the ray imaging equipment. Detectors for detecting radioactive rays generally include gas detector, scintillation detector, and semiconductor detector, in which the semiconductor detector can obtain the best energy resolution.

The semiconductor detector directly absorbs radioactive rays to generate electron-hole pairs through the photoelectric effect, Compton scattering, and electron pair generation, and movement of the electron-hole pairs in an external electric field results in basic electrical signals of the detector. For such a semiconductor radiation detector, the light absorption layer can use a variety of semiconductor materials such as silicon (Si) and amorphous selenium (a-Se) according to different uses, but these materials have disadvantages such as the need to increase the bias voltage, complex process and low sensitivity. Therefore, it is very urgent and necessary to find a material having high sensitivity to radioactive rays as an absorption layer of the semiconductor radiation detector.

### SUMMARY OF THE PRESENT INVENTION

In view of the above-described problems, the present invention provides a semiconductor radiation detector based on Bi-based quaternary halide single crystal and a manufacturing method thereof, and aims to obtain a high-performance, non-toxic and stable semiconductor radiation detector so as to solve problems such as complex process, low sensitivity, environmental pollution and poor stability in the prior art as well as the problem that the property indexes such as sensitivity, working bias, stability and environmental pollution cannot be considered simultaneously.

Specifically, the present invention provides a semiconductor radiation detector based on inorganic double perovskite single crystal, comprising:

a light absorption layer which is made of Bi-based quaternary halide single and used for absorbing high-energy rays to generate electron-hole pairs;

two charge selective contact layer which are respectively attached to both sides of the light absorption layer so as to selectively extract the electron-hole pairs generated in the light absorption layer; and two electrodes which are respectively in direct contact with the two charge selective contact layers and used as positive and negative electrodes of the semiconductor radiation detector (the positive electrode is in direct contact with the electron selective contact layer and the negative electrode is in direct contact with the hole selective contact layer).

Preferably, the chemical constitution of the Bi-based quaternary halide is Cs₂AgBiX₆, where X represents Cl or Br.

Preferably, the two charge selective contact layers are respectively an electron selective contact layer and a hole selective contact layer.

Preferably, the electron selective contact layer includes one or more of buckminsterfullerene (C₆₀), fullerene derivatives (PCBM), titanium dioxide (TiO₂) and zinc oxide (ZnO), or the electron selective contact layer may be removed.

Preferably, the hole selective contact layer includes nickel oxide (NiO), or the hole selective contact layer may be removed.

According to another aspect of the present invention, there is further provided a manufacturing method of the semiconductor radiation detector, comprising:

(1) weighting CsX, AgX, and BiX₃ (X represents Cl or Br) at a molar ratio of 2:1:1, adding them into a hydrogen halide solution (HX, where X represents Cl or Br), heating the solution to 110 to 130 degrees Celsius for sufficient dissolution, and then cooling the solution to 50 to 70 degrees Celsius at a rate of less than 1 degrees Celsius per hour so as to precipitate crystal, thereby obtaining Bi-based quaternary halide single crystal;

(2) drying the obtained crystal; and

(3) preparing gold electrodes on upper and lower surfaces of the crystal, respectively.

Preferably, the method further comprises a step between the step (2) and the step (3): preparing an electron selective contact layer and a hole selective contact layer on upper and lower surfaces of the crystal, respectively.

The present invention proposes using Bi-based quaternary halide single crystal as a light absorption layer of the semiconductor radiation detector, which has the following advantages:

the Bi-based quaternary halide single crystal material has a suitable band gap, high mobility, high carrier lifetime and high stability, and is a novel material of the light absorption layer of the semiconductor radiation detector. Compared with the traditional radiation detectors using cadmium telluride, amorphous selenium and silicon, the semiconductor radiation detector in the present invention has high sensitivity and low working bias, and compared with the recently proposed methylamine lead bromide, the Bi-based quaternary halide single crystal is non-toxic and stable while ensuring the performance.

### BRIEF DESCRIPTION OF THE DRAWINGS

FIG. 1 is a schematic cross-sectional view of the structure of a semiconductor radiation detector according to the present invention;

FIG. 2 is a graph showing a relationship between absorption of 30 keV energy rays and thickness of different materials obtained by theoretical calculations;

FIG. 3 is an explanatory diagram of the function of the semiconductor radiation detector according to the present invention;

FIG. 4 shows a measured value of μ·τ; and

FIG. 5 is a graph of the measured IT.

### DETAILED DESCRIPTION OF THE EMBODIMENTS

For clear understanding of the objectives, features and advantages of the present invention, detailed description of the present invention will be given below in conjunction with accompanying drawings and specific embodiments. It should be noted that the embodiments described herein are only meant to explain the present invention, and not to limit the scope of the present invention.

The present invention will be further described below in conjunction with embodiments.

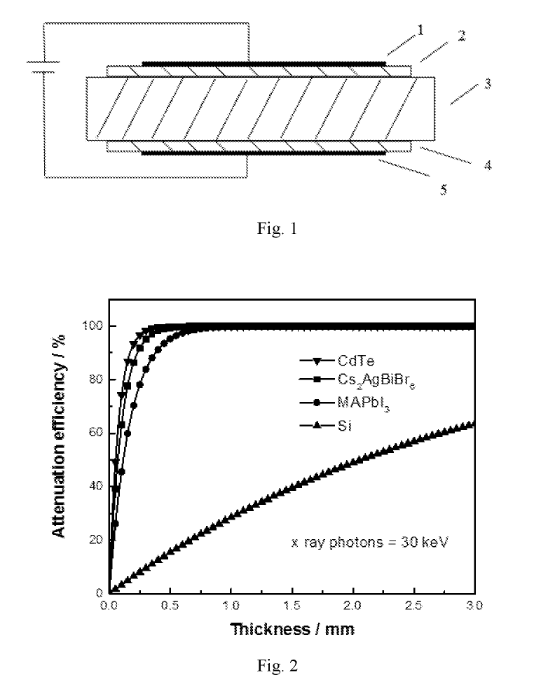

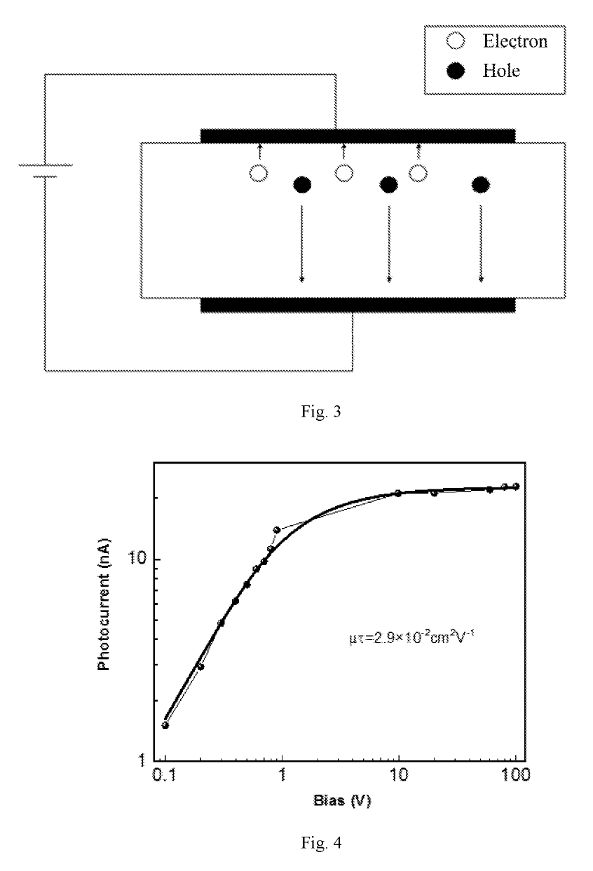

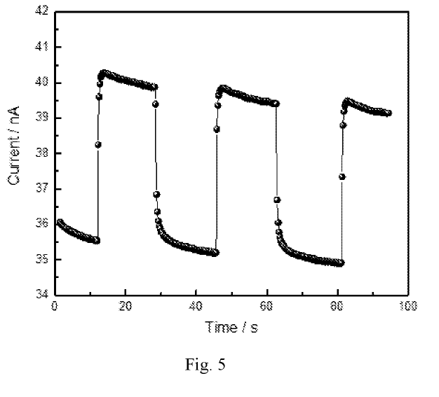

FIG. 1 is a schematic cross-sectional view of the structure of a semiconductor radiation detector according to the present invention; FIG. 2 is a graph showing a relationship between absorption of 30 keV energy rays and thickness of different materials obtained by theoretical calculations; FIG. 3 is an explanatory diagram of the function of the semiconductor radiation detector according to the present invention; FIG. 4 shows a measured value of μ·τ (μrepresents the carrier mobility, and τ represents the carrier lifetime. The multiplication of the two is large, indicating that the carriers can be exported by applying only a small bias voltage, so that the detector has better sensitivity); and FIG. 5 is a graph of the measured IT, and from the graph of IT, the current change of the detector under conditions of high-energy ray on and off can be observed.

As shown in FIG. 1, the semiconductor radiation detector in this example includes: a light absorption layer 3 made of Bi-based quaternary halide single crystal; an electron selective contact layer 2 and a hole selective contact layer 4 provided on upper and lower sides of the light absorption layer 3; and an electrode 1 and an electrode 5 respectively provided on the electron selective contact layer 2 and the hole selective contact layer 4. Noted that the electron selective contact layer 2 and the hole selective contact layer 4 can be removed, so that the two electrodes directly contact the upper and lower sides of the light absorption layer 3.

The electron selective contact layer 2 and the hole selective contact layer 4 are provided to inhibit the dark current by utilizing the significant difference in the charge transfer effect between electrons and holes in the carrier in the semiconductor. A positive bias is applied to the electrode 1, and in order to suppress the injection of holes, for example, buckminsterfullerene (C₆₀), fullerene derivatives (PCBM), titanium dioxide (TiO₂) and zinc oxide (ZnO) can be used as the electron selective contact layer. A reverse bias is applied to the electrode 5, and in order to suppress the injection of electrons, nickel oxide (NiO) is used as the hole selective contact layer.

The semiconductor radiation detector in this embodiment applies a positive bias to the electrode 1, and the high-energy ray is incident from the electrode 1 through the electron selective contact layer 2 and then absorbed by the light absorption layer 3 of Bi-based quaternary halide single crystal, so that electron-hole pairs are generated in the light absorption layer 3 of Bi-based quaternary halide single crystal and respectively move to the two electrodes, thereby generating a current.

As shown in FIG. 2, the Bi-based quaternary halide single crystal used as the light absorption layer of the semiconductor radiation detector has an absorption coefficient which is larger than that of silicon (Si) and comparable to that of cadmium telluride (CdTe) and organic-inorganic perovskite (MAPbI₃). Thus, as the light absorption layer of the semiconductor radiation detector, this material has some advantages on absorption, that is, in a case of the same thickness, the absorption efficiency of the Bi-based quaternary halide in high-energy rays is only slightly lower than that of the cadmium telluride (CdTe), and is higher than that of silicon (Si) and organic-inorganic perovskite (MAPbI₃).

As shown in FIG. 3, when a positive bias is applied to allow the electrode (i.e., the voltage applying electrode 6) on the incident side of the high-energy ray to have a higher potential than that of the carrier electrode 1, the electrons generated by the incident of the high-energy ray move toward the X-ray incident side, while the holes move to the opposite side. Whether the electron-hole pairs generated in this process can reach the corresponding electrode export is determined by carrier mobility μ, carrier lifetime τ and applied bias E. The larger the value of μ·τ is, the smaller the applied bias for exporting the electrons and holes will be, and the higher the sensitivity of the semiconductor radiation detector using this material as a light absorption layer. For the currently used light absorption layer of the semiconductor radiation detector, the order of magnitude of μ·τ is −5 to −18 and the required working bias is on the order of kV, while for the Bi-based quaternary halide single crystal proposed in the invention, the order of magnitude of μ·τ is −2 (as shown in FIG. 4) and a working bias of only 1V to 10V is needed to export the carriers, which makes the semiconductor radiation detector have higher sensitivity. FIG. 4 shows a changing curve of the photocurrent over the bias, and the order of magnitude of μ·τ obtained by curve fitting is up to −2, which is much higher than that (−5 to −8) of the common material of the light absorption layer of the semiconductor radiation detector. This shows that the present invention has a significant advantage over other materials in terms of the key value μ·τ.

A graph of IT in a case of a bias of 0.1V and the irradiation of 35 keV X-ray is shown in FIG. 5. In the figure, when the photocurrent rises, it indicates that the X-ray is on, and when the photocurrent descends, it indicates that the X-ray is off. FIG. 5 shows a test example indicating that the detector has better light-dark current ratio and good detection performance.

### Embodiment 1

In this embodiment, the preparation of cesium silver bismuth bromine (Cs₂AgBiBr₆) crystal and the manufacturing of a semiconductor radiation detector using this crystal will be described.

Silver bromide (AgBr, 0.188 g, 1 mmol), bismuth bromide (BiBr₃, 0.449 g, 1 mmol) and cesium bromide (CsBr, 0.426 g, 2 mmol) are added into a 10 ml solution of hydrobromic acid (HBr), the solution is heated to 130 degrees Celsius to fully dissolve the solute, and then the solution is cooled to 60 degrees Celsius at a rate of 1 degrees Celsius per hour to precipitate the crystal, thereby obtaining the Cs₂AgBiBr₆ crystal.

Gold electrodes with a thickness of 80 nm are then formed on upper and lower surfaces of the crystal by thermal evaporation.

### Embodiment 2

In this embodiment, the preparation of cesium silver bismuth bromine (Cs₂AgBiBr₆) crystal and the manufacturing of a semiconductor radiation detector by adding charge selective contact layers on the crystal will be described.

Silver bromide (AgBr, 0.188 g, 1 mmol), bismuth bromide (BiBr₃, 0.449 g, 1 mmol) and cesium bromide (CsBr, 0.426 g, 2 mmol) are added into a 10 ml solution of hydrobromic acid (HBr), the solution is heated to 130 degrees Celsius to fully dissolve the solute, and then the solution is cooled to 60 degrees Celsius at a rate of 1 degrees Celsius per hour to precipitate the crystal, thereby obtaining the Cs₂AgBiBr₆ crystal.

Buckminsterfullerene (C₆₀) is formed on the upper surface of the crystal by thermal evaporation.

Gold electrodes with a thickness of 80 nm are then formed on the upper and lower surfaces of the crystal by thermal evaporation.

### Embodiment 3

In this embodiment, the preparation of cesium silver bismuth bromine (Cs₂AgBiBr₆) crystal and the manufacturing of a semiconductor radiation detector using this crystal will be described.

Silver bromide (AgCl, 0.144 g, 1 mmol), bismuth bromide (BiBr₃, 0.317 g, 1 mmol) and cesium bromide (CsCl, 0.328 g, 2 mmol) are added into a 10 ml solution of hydrochloric acid (HCl), the solution is heated to 120 degrees Celsius to fully dissolve the solute, and then the solution is cooled to 60 degrees Celsius at a rate of 0.5 degrees Celsius per hour to precipitate the crystal, thereby obtaining the Cs₂AgBiCl₆ crystal.

Gold electrodes with a thickness of 80 nm are then formed on upper and lower surfaces of the crystal by thermal evaporation.

It can be seen from the embodiments that the semiconductor radiation detector manufactured by the present invention has advantages such as high sensitivity, good stability and environmental friendliness.

While particular embodiments of the present invention have been shown and described, it will be obvious to those skilled in the art that changes and modifications may be made without departing from the spirit and scope of the present invention.

1. A semiconductor radiation detector based on Bi-based quaternary halide single crystal, comprising a light absorption layer and two electrodes, wherein,
the light absorption layer is made of Bi-based quaternary halide single crystal, and is used for absorbing high-energy rays to generate electron-hole pairs; and
the two electrodes are respectively in direct contact with the light absorption layer and used as positive and negative electrodes of the semiconductor radiation detector.

2. The semiconductor radiation detector of claim 1, wherein two charge selective contact layers are respectively provided between the light absorption layer and the two electrodes to facilitate separation and export of electrons and holes.

3. The semiconductor radiation detector of claim 1, wherein the Bi-based quaternary halide is Cs2AgBiX6, where X represents Cl or Br.

4. The semiconductor radiation detector of claim 2, wherein the two charge selective contact layers are respectively an electron selective contact layer for exporting electrons generated in the light absorption layer and a hole selective contact layer for exporting holes generated in the light absorption layer.

5. The semiconductor radiation detector of claim 3, wherein the electron selective contact layer includes one of buckminsterfullerene (C60), fullerene derivatives (PCBM), titanium dioxide (TiO2) and zinc oxide (ZnO).

6. The semiconductor radiation detector of claim 3, wherein the hole selective contact layer is nickel oxide (NiO).

7. The semiconductor radiation detector of claim 1, wherein the two electrodes are made by gold material.

8. The semiconductor radiation detector of claim 1, wherein the high-energy rays include X-ray and gamma-ray with energy greater than 20 KeV.

9. A manufacturing method of the semiconductor radiation detector of claim 1, comprising:
(1) weighting CsX, AgX, and BiX3 (X represents Cl or Br) at a molar ratio of 2:1:1, adding them into a hydrogen halide solution (HX, where X represents Cl or Br), heating the solution to 110 to 130 degrees Celsius for sufficient dissolution, and then cooling the solution to 50 to 70 degrees Celsius at a rate of less than 1 degrees Celsius per hour so as to precipitate crystal, thereby obtaining Bi-based quaternary halide single crystal;
(2) drying the obtained crystal; and
(3) preparing gold electrodes on upper and lower surfaces of the crystal, respectively.

10. A manufacturing method of the semiconductor radiation detector of claim 2, comprising:
(1) weighting CsX, AgX, and BiX3 (X represents Cl or Br) at a molar ratio of 2:1:1, adding them into a hydrogen halide solution (HX, where X represents Cl or Br), heating the solution to 110 to 130 degrees Celsius for sufficient dissolution, and then cooling the solution to 50 to 70 degrees Celsius at a rate of less than 1 degrees Celsius per hour so as to precipitate crystal, thereby obtaining Bi-based quaternary halide single crystal;
(2) drying the obtained crystal;
(3) preparing an electron selective contact layer and a hole selective contact layer on upper and lower surfaces of the crystal, respectively; and
(4) preparing gold electrodes on the charge selective contact layers of the crystal, respectively.
